(19) United States
(12) Patent Application Publication
(10) Pub. No.: US 2024/0362395 A1
(43) Pub. Date: Oct. 31, 2024

(54) LAYOUT CORRECTION METHOD AND MASK MANUFACTURING METHOD USING THE SAME

(71) Applicant: Samsung Electronics Co., Ltd., Suwon-si (KR)

(72) Inventors: Yangwoo Heo, Suwon-si (KR); Bayram Yenikaya, Suwon-si (KR); Xin Li, Suwon-si (KR); Sangwook Kim, Suwon-si (KR)

(21) Appl. No.: 18/394,330

(22) Filed: Dec. 22, 2023

(30) Foreign Application Priority Data
Apr. 27, 2023 (KR) 10-2023-0055674

(51) Int. Cl. G06F 30/398; G03F 1/36

(52) U.S. Cl. CPC G06F 30/398; G03F 1/36

(57) ABSTRACT

A layout correction method for a semiconductor device includes receiving a design layout including at least a target layer and a reference layer, detecting target edges including target patterns in the target layer, and detecting reference edges including reference patterns in the reference layer, determining a dissection point in a section intersecting a space between reference patterns on a target edge having three or more intersecting reference edges, generating segments by dissecting the target edges based on dissection points set for the target edges, setting an evaluation point at an intermediate point of a section intersecting a reference pattern in a segment intersecting the reference pattern, among the segments, determining a movement amount of segments having evaluation points set on the segments by inputting a feature measured at the evaluation points to a layout correction model, and generating a corrected layout by moving the segments based on the movement amount.

### CROSS-REFERENCE TO RELATED APPLICATION(S)

This application claims benefit of priority to Korean Patent Application No. 10-2023-0055674 filed on Apr. 27, 2023 in the Korean Intellectual Property Office, the disclosure of which is incorporated herein by reference in its entirety.

### BACKGROUND

The present inventive concept relates to a layout correction method for a semiconductor, and a mask manufacturing method using the same.

In general, patterns of a semiconductor chip may be formed by an exposure (photolithography) process and an etching process. First, a layout of a circuit pattern of a semiconductor chip to be formed on a wafer may be designed, and a mask may be manufactured based on the designed layout. When the circuit pattern on the mask is transferred onto the wafer by the exposure process to form a circuit pattern on the wafer, a gap may occur between the transferred circuit pattern on the wafer and the designed circuit pattern of the layout. Such a difference may be due to an optical proximity effect in the exposure process, a loading effect in the etching process, or the like.

In order to accurately transfer the designed circuit pattern onto the wafer, a process proximity correction (PPC) technique may be used to correct the designed circuit pattern in consideration of deformation of the transferred circuit pattern.

Meanwhile, when circuit patterns are stacked in a plurality of layers on a semiconductor substrate, a gap between a designed circuit pattern and a transferred circuit pattern of a target layer may occur due to a film-like material of a lower layer, a step difference in a surface, or the like.

### SUMMARY

Some embodiments of the present inventive concept provide a layout correction method and a mask manufacturing method in which a designed circuit pattern may be accurately transferred onto a wafer by performing PPC in consideration of a pattern of a lower layer.

According to some embodiments of the present inventive concept, a layout correction method for a semiconductor device includes receiving a design layout including at least a target layer and a reference layer, detecting target edges including target patterns in the target layer, and detecting reference edges including reference patterns in the reference layer, determining a dissection point in a section intersecting a space between reference patterns on a target edge having three or more intersecting reference edges, among the target edges, generating segments by dissecting the target edges based on dissection points set for the target edges, wherein the dissection points comprise the dissection point, setting an evaluation point at an intermediate point of a section intersecting a reference pattern among the reference patterns of the reference patterns in a segment intersecting the reference pattern, among the segments, determining respective movement amounts of segments having evaluation points including the evaluation point set on the segments by inputting a feature measured at the evaluation points to a layout correction model, generating a corrected layout by moving the segments based on the movement amount, and forming a mask based on the corrected layout.

According to some embodiments of the present inventive concept, a layout correction method for a semiconductor device includes measuring data at measurement points that are at an intermediate point of a section intersecting a reference pattern of a reference layer on a target edge of target layers, for determining a design layout and a post-formation layout, generating a layout correction model by performing machine learning based on the data that was measured, dissecting edges intersecting two or more reference patterns, among target edges including the target edge of a target layer among the target layers, into segments respectively intersecting one reference pattern of the two or more reference patterns, in a design layout for manufacturing the semiconductor device, generating a corrected layout by applying data measured at evaluation points set by criteria consistent with the measurement points, for the segments, to the layout correction model, and forming a mask based on the corrected layout.

According to some embodiments of the present inventive concept, a mask manufacturing method for a semiconductor device includes receiving a design layout including at least a target layer and a reference layer below the target layer, generating segments by dissecting target edges of the target layer based on sections intersecting a space between reference patterns of the reference layer, setting an evaluation point at an intermediate point of a intersecting section intersecting a reference pattern, in segments having the intersecting section, respectively, among the segments that were generated, generating a corrected layout by applying respective features at evaluation points to a process proximity correction (PPC) model and by moving segments having the evaluation points according to a result of the applying, generating a mask layout by performing optical proximity correction (OPC) on the corrected layout, and manufacturing a mask based on the mask layout.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram illustrating a computing system performing layout correction according to some embodiments.

FIGS. 2A to 2C are views illustrating a layout correction method.

FIG. 3 is a flowchart illustrating a method of generating a layout correction model.

FIG. 4 is a flowchart illustrating a method for generating a corrected layout.

FIG. 5 is a view illustrating a method of generating a layout correction model.

FIG. 6 is a view illustrating a method of generating a layout correction model according to a comparative example and/or some embodiments.

FIG. 7 and FIG. 9 are views illustrating a layout correction method according to some embodiments.

FIG. 8 and FIG. 10 are flowcharts illustrating a layout correction method according to some embodiments.

FIGS. 11A and 11B are views for comparing and explaining layout correction results according to a comparative example and/or some embodiments.

FIGS. 12A and 12B are views illustrating a comparison between a position in which a measurement point is generated and a position in which an evaluation point is generated according to some embodiments.

FIG. 13 is a view illustrating a method of manufacturing a mask according to some embodiments.

FIG. 14 is a view illustrating a method of manufacturing a semiconductor chip according to some embodiments.

### DETAILED DESCRIPTION

Hereinafter, preferred embodiments will be described with reference to the accompanying drawings.

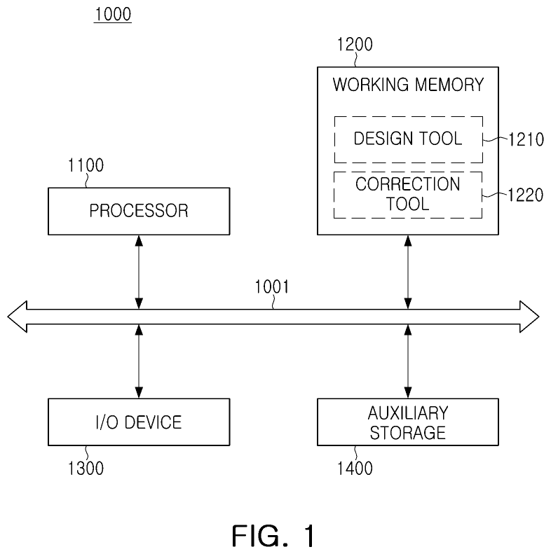

FIG. 1 is a block diagram illustrating a computing system performing layout correction according to some embodiments.

Referring to FIG. 1, a computing system 1000 may include at least one processor 1100, a working memory 1200, an input/output device 1300, and an auxiliary storage device 1400, connected to a system bus 1001.

The computing system 1000 may be provided as a dedicated device for generating/correcting a layout correction model or as a dedicated device for performing semiconductor design including the same. For example, the computing system 1000 may include various design and verification simulation programs. The processor 1100, the working memory 1200, the input/output device 1300, and the auxiliary storage device 1400 may be electrically connected to each other and may exchange data with each other through the system bus 1001. A configuration of the system bus 1001 is not limited to the above description, and may further include a mediation circuitry or module for efficient management.

The processor 1100 may be implemented to execute at least one instruction. For example, the processor 1100 may be implemented to execute software (application programs, operating systems, or device drivers) to be executed in the computing system 1000. The processor 1100 may execute an operating system loaded into the working memory 1200. The processor 1100 may execute various application programs to be driven based on the operating system. For example, the processor 1100 may be a central processing unit (CPU), a microprocessor, an application processor (AP), or any processing device similar thereto.

The working memory 1200 may be implemented to store the at least one instruction. For example, the operating system or the application programs may be loaded into the working memory 1200. When the computing system 1000 boots, an OS image stored in the auxiliary storage device 1400 may be loaded into the working memory 1200 according to a booting sequence. All input/output operations of the computing system 1000 may be supported by the operating system. Similarly, application programs selected by a user and/or for providing basic services may be loaded into the working memory 1200. In particular, a design tool 1210 for designing a semiconductor and generating a design layout or a correction tool 1220 for performing layout correction on the design layout may be loaded into the working memory 1200 from the auxiliary storage device 1400.

In addition, the working memory 1200 may be a volatile memory such as a dynamic random access memory (DRAM), a static random access memory (SRAM), or the like, or may be a non-volatile memory such as a flash memory, a phase-change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like.

The design tool 1210 may perform a function of changing shapes and positions of specific layout patterns differently from those defined by a design rule (DR). In addition, the design tool 1210 may perform a design rule check (DRC) under a changed bias data condition.

The correction tool 1220 may perform layout correction on a design layout. A layout may be a physical indication by which a circuit designed for a semiconductor chip may be transferred onto a wafer, and may include a plurality of patterns. For example, the design layout may be provided as coordinate values of contours of patterns included in the design layout from a computer aided design (CAD) system. In particular, the patterns may include repeating patterns in which the same shape is repeated, and the patterns may be provided in a combination of polygons such as a triangle or a quadrangle.

The correction tool 1220 may perform process proximity correction (PPC), optical proximity correction (OPC), or the like. PPC may refer to layout correction for compensating for deformation of a circuit pattern formed on a wafer due to performing a semiconductor process such as an etching process or the like. The correction tool 1220 may generate a PPC model by performing machine learning based on various data, and may perform layout correction by executing the PPC model for a design layout.

The correction tool 1220 may further perform OPC. OPC may refer to layout correction for compensating for deformation of a circuit pattern transferred to a wafer due to an optical proximity effect in an exposure process.

The input/output device 1300 may control user input and user output from a user interface device. For example, the input/output device 1300 may receive information from a designer by using an input device such as a keyboard, a keypad, a mouse, a touchscreen, or the like. Using the input/output device 1300, the designer may receive information about a semiconductor region or data paths requiring adjusted operating characteristics. In addition, the input/output device 1300 may display processing procedures, processing results, or the like of the design tool 1210 or the correction tool 1220 by including an output device such as a printer, a display, or the like.

The auxiliary storage device 1400 may be provided as a storage medium of the computing system 1000. The auxiliary storage device 1400 may store application programs, an OS image, and various data. The auxiliary storage device 1400 may be provided as a mass storage device such as a memory card (an MMC, an eMMC, an SD, a Micro SD, or the like), a hard disk drive (HDD), a solid state drive (SSD), a universal flash storage (UFS), or the like.

As a degree of integration of a semiconductor chip increases, a plurality of layers including circuit patterns tend to be stacked on the semiconductor chip. When the plurality of layers are stacked, a process variation in circuit pattern of a certain layer may be affected by circuit patterns formed on a lower layer below the certain layer.

For example, a width of a circuit pattern exposed on a wafer may be changed according to an etching process. A variation in pattern by the etching process may be referred to as etch skew. A deviation in etch skew of the layer may occur due to a difference in material composition of a surface of the lower layer or a step difference in the surface, by the circuit patterns formed on the lower layer below the certain layer.

For example, an upper layer may include a gate pattern of a semiconductor device, and a lower layer may include a plurality of active patterns overlapping the gate pattern. A deviation in etch skew of the gate pattern may occur due to a difference in material composition or a difference in surface level between a region in which the plurality of active patterns are formed and a region in which the plurality of active patterns are not formed.

When patterns of a lower layer are considered to perform PPC on a certain target layer, a deviation in etch skew due to the patterns of the lower layer may be compensated for.

According to some embodiments, the computing system 1000 may generate data by measuring various features at measurement points in positions of a design layout in which patterns of a target layer and patterns of a lower layer overlap, and may generate a layout correction model by performing machine learning based on the data.

Further, the computing system 1000 may set evaluation points in positions of a design layout to be subjected to layout correction in which patterns of a target layer and patterns of a lower layer overlap, and may correct the patterns of the target layer by applying data measured at the evaluation points to the layout correction model.

According to some embodiments, a layout correction model may be generated based on data measured from measurement points affected by a process variation caused by patterns of a lower layer. Therefore, the layout correction model may be used to compensate for a process variation caused by patterns of a lower layer.

Also, evaluation points for applying the layout correction model may be selected in positions consistent with the measurement points. Therefore, a corrected layout that has been corrected using the layout correction model may improve compatibility with a layout used when learning the layout correction model. As a result, in a semiconductor chip manufactured based on the corrected layout, a process variation of a target layer caused by patterns of a lower layer may be effectively compensated for.

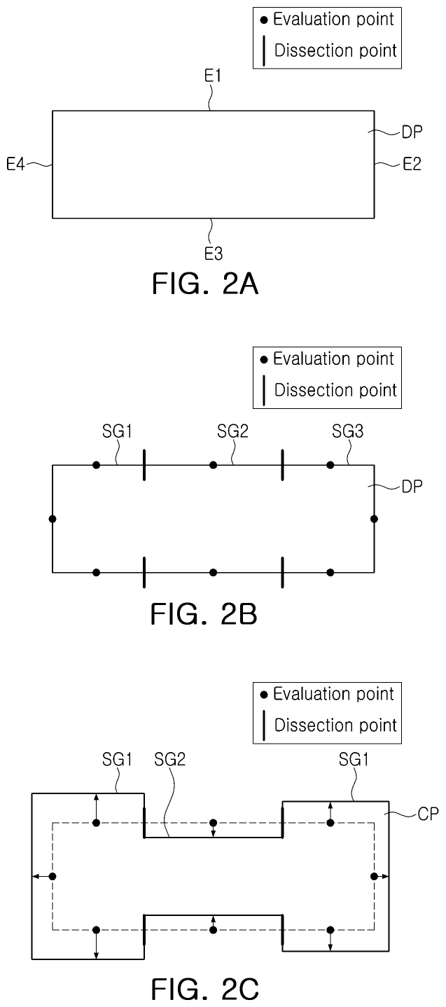

Hereinafter, a layout correction method according to some embodiments will be described in detail with reference to FIGS. 2 to 12.

FIGS. 2A to 2C are views illustrating a layout correction method.

FIG. 2A illustrates a design pattern DP included in a design layout. The design pattern DP of FIG. 2A may have a rectangular shape. The design pattern DP may be defined by a closed loop. For example, the closed loop may include a plurality of edges E1, E2, E3, and E4. For design layout correction, edges of the design pattern DP of FIG. 2A may be dissected into a plurality of segments.

FIG. 2B illustrates a design pattern DP in which edges are dissected into segments.

Referring to FIG. 2B, a plurality of dissection points may be set for dissecting edges into segments. For example, a first edge E1 of FIG. 2A may be dissected into three segments SG1, SG2, and SG3 by two dissection points. Similarly, a third edge E3 may be dissected into three segments. No dissection point may be set on second and fourth edges E2 and E4, and the second and fourth edges E2 and E4 may be a single segment, respectively.

An evaluation point may be set for segments. Layout correction such as PPC may include an operation of changing a shape of a design pattern DP by moving segments of the design pattern DP. To determine a movement amount of each of the segments, features measured in a position representing each of the segments may be used. A position representing a segment may be referred to as an evaluation point of the segment.

In an example of FIG. 2B, an evaluation point may be set at an intermediate point of each of the segments. A detailed method of setting dissection points and evaluation points according to some embodiments will be described later.

FIG. 2C illustrates a correction pattern CP included in a corrected layout.

The correction pattern CP may be generated by moving the segments of the design pattern DP by a movement amount determined using a layout correction model. For example, each of the segments may move in a direction in which the design pattern DP extends or contracts. In an example of FIG. 2C, according to a movement amount determined for each of the first to third segments SG1 to SG3, the first and third segments SG1 and SG3 may move in a direction in which the design pattern DP extends. and the second segment SG2 may move in a direction in which the design pattern DP contracts, which is opposite the direction the design pattern DP extends.

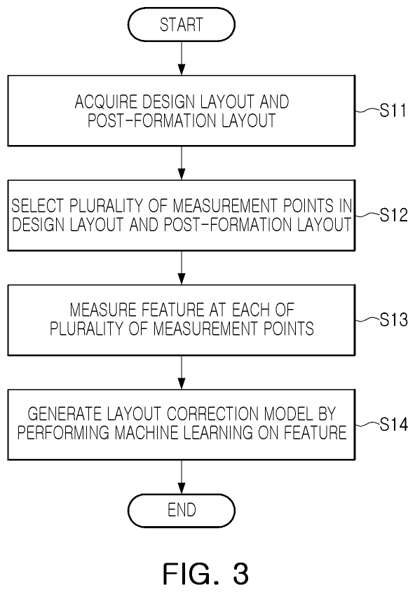

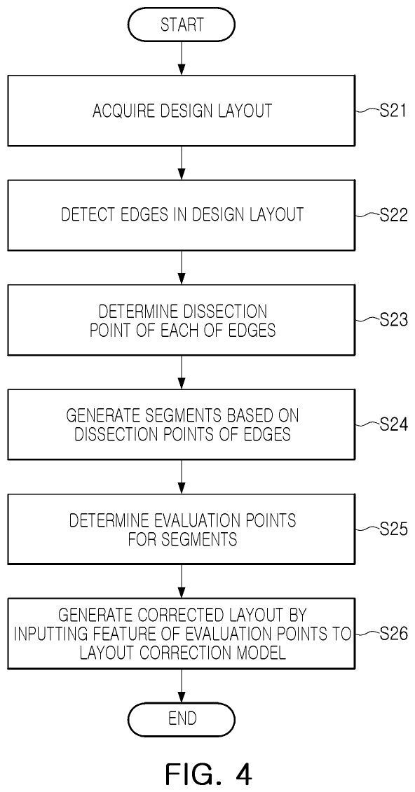

Referring to FIGS. 3 and 4, a method of generating a layout correction model and a method for generating a corrected layout using the layout correction model are described.

FIG. 3 is a flowchart illustrating a method of generating a layout correction model.

In S11, a computing system 1000 may acquire a design layout and a post-formation layout corresponding to the design layout. The design layout and the post-formation layout may be used as training data of machine learning for generating a layout correction model.

The design layout may include a structure to be manufactured by a semiconductor process and may have an image format. The post-formation layout may include a structure formed on a wafer by performing the semiconductor process using the design layout, and may have an image format.

For example, the post-formation layout may be an after-cleaning-inspection (ACI) layout including a structure after an exposure process, a development process, an etching process, and a cleaning process are completed on the wafer. The present inventive concept is not limited thereto, and the post-formation layout may be an after-develop-inspection (ADI) layout including a structure after an exposure process and a development process are completed on the wafer.

In S12, the computing system 1000 may select a plurality of measurement points in the design layout and the post-formation layout. The design layout and the post-formation layout may include a plurality of layers, respectively. The measurement points may be selected from patterns included in each of the plurality of layers.

In each of the design layout and the post-formation layout, the plurality of layers may include at least a target layer and a lower layer below the target layer. The lower layer below the target layer may include circuit patterns formed below circuit patterns of the target layer on the wafer.

According to some embodiments, measurement points of the target layer may be selected in positions in which patterns of the target layer and patterns of the lower layer overlap. For example, an intermediate point of a section crossing a pattern of the lower layer from an edge of the target layer may be determined as a measurement point. As used herein, two elements crossing one another may intersect one another in at least one plane but may or may not contact one another.

In S13, the computing system 1000 may measure a feature at each of the plurality of measurement points. For example, a critical dimension (CD) may be measured based on a plurality of measurement points respectively selected from the design layout and the post-formation layout. CD may refer to a width of a pattern. The width of the pattern that is used as the CD may be measured at the widest point, narrowest point, or may be an average width of the pattern, as non-limiting examples.

The feature that may be measured at the measurement points is not limited to CD. For example, features may further include a distance between the measurement point and an adjacent pattern, a pattern density in a region within a predetermined range from the measurement point, or other measurements or features.

In S14, the computing system 1000 may generate a layout correction model by performing machine learning on the feature. For example, a degree of process variation such as etch skew or the like may be calculated, based on a CD measurement result of each of the design layout and the post-formation layout. The machine learning may be performed based on the CD measurement result and a degree of etch skew.

When CD of the design layout is input, the generated layout correction model may predict etch skew of the post-formation layout based on the CD, and may output a corrected layout for correcting the predicted etch skew.

According to some embodiments, since the measurement points of the target layer for generating the layout correction model may be formed at points overlapping the patterns of the lower layer, measurement data at the measurement points may reflect process variation by the patterns of the lower layer. Therefore, when the layout correction model is used, it is possible to effectively predict the process variation by the patterns of lower layers and to compensate for the predicted process variation.

FIG. 4 is a flowchart illustrating a method for generating a corrected layout.

In S21, a computing system 1000 may acquire a design layout to be corrected. For example, the design layout may be provided from a host computer or a server in a semiconductor manufacturing facility. The design layout may include a structure of a semiconductor device to be manufactured. The design layout may be referred to as a design layout for manufacturing to distinguish the same from a design layout for learning used to generate a layout correction model. To accurately form the structure to be manufactured on a semiconductor chip, the design layout may be corrected in S22 to S26.

In S22, the computing system 1000 may detect edges in the design layout. The edges may define patterns and a space. For example, a region in closed curves formed by the edges may define the patterns, and a region excluding the patterns may be defined as the space.

In S23, the computing system 1000 may determine a dissection point of each of the edges. According to some embodiments, when an edge included in a target layer crosses a space between patterns of a lower layer, a dissection point may be set in a section crossing the space from the edge. A method of determining the dissection point of the target layer will be described in detail later.

In S24, the computing system 1000 may generate segments based on the dissection points of the edges. For example, an edge having no dissection point may be a single segment, and an edge having at least one dissection point may be a plurality of segments dissected based on the dissection point.

In S25, the computing system 1000 may determine evaluation points for the segments. According to some embodiments, when a segment of the target layer crosses a pattern of the lower layer, an intermediate point of a section crossing the pattern in the segment may not be determined as an evaluation point. When the segment of the target layer and the pattern of the lower layer do not overlap, an evaluation point may not be set for the segment. A method for determining the evaluation point will be described in detail later.

In S26, the computing system 1000 may generate a corrected layout by inputting a feature of the evaluation points to the layout correction model. For example, the layout correction model may predict a post-formation layout corresponding to the design layout for manufacturing based on the feature at the evaluation points. In addition, the layout correction model may generate the corrected layout by determining a movement amount of segments capable of compensating for a process variation that may occur in the post-formation layout, based on the predicted post-formation layout.

The feature of the evaluation points may include at least one of a CD, a distance from an adjacent pattern, or a pattern density in a region of a predetermined range. For example, CD measured based on the evaluation points into the layout correction model may be input to predict an etch step difference of the post-formation layout, and to determine a movement amount of the segments to compensate for the predicted etch step difference.

According to some embodiments, a measurement point used to generate a layout correction model and an evaluation point used to apply the layout correction model may be set as consistent criteria. In particular, since the measurement point and the evaluation point may be selected at points overlapping patterns of the lower layer, etch skew caused by the pattern of the lower layer may be effectively compensated.

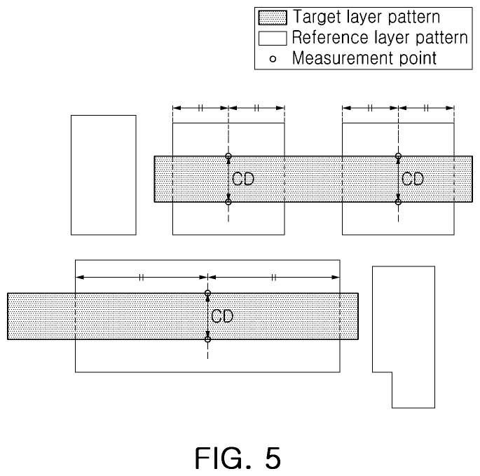

Hereinafter, a method of generating a layout correction model and a layout correction method according to some embodiments will be described in more detail using FIGS. 5 to 10.

FIG. 5 is a view illustrating a method of generating a layout correction model.

FIG. 5 is a view illustrating overlapping patterns of a target layer and patterns of a reference layer. For example, the reference layer may be a lower layer of the target layer. For example, the target layer may include gate patterns of a semiconductor device, and the reference layer may include active patterns of the semiconductor devices.

In the target layer and the reference layer, the patterns may be defined by a closed curve formed by edges. Hereinafter, a pattern of the target layer, an edge of the target layer, a pattern of the reference layer, and an edge of the reference layer may be referred to as a target pattern, a target edge, a reference pattern, and a reference edge, respectively.

Data on target patterns may be collected to generate a layout correction model using machine learning. For example, measurement points may be selected from target patterns, and features measured at the measurement points and process variation information related to the features may be collected.

According to some embodiments, a measurement point may be selected from a portion of the target edge overlapping the reference pattern. Specifically, the measurement point may be selected as an intermediate point of a section crossing the reference pattern from the target edge. FIG. 5 illustrates measurement points selected from target patterns.

Various features may be measured at the measurement points. For example, a CD of the target patterns may be measured based on the measurement points. FIG. 5 illustrates positions in which a CD of target patterns is measured based on measurement points. As various features, a distance from a measurement point to an adjacent pattern, a pattern density in a distance range determined from the measurement point, or the like may be further measured. Further, process variations such as etch skew may be further measured based on the features.

According to some embodiments, since measurement points may be selected in position overlapping reference patterns, data measured at the measurement points may have process variation information by the reference patterns. Therefore, the layout correction model generated based on the data may effectively predict process variations due to the reference patterns and may compensate for the process variations.

When evaluation points set on a design layout for manufacturing are inconsistent with the measurement points, conformity between a post-formation layout predicted by applying the layout correction model to the evaluation points and a post-formation layout for learning may be degenerated.

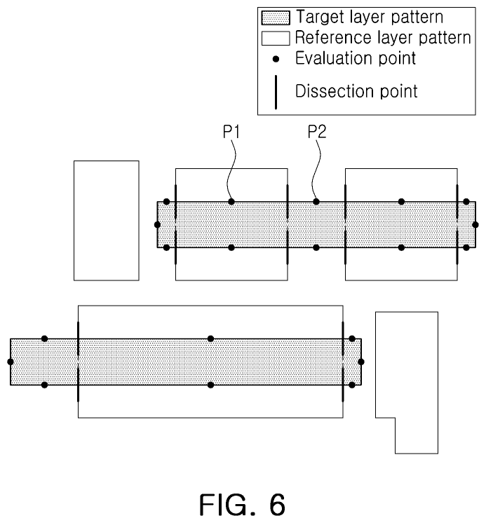

FIG. 6 is a view illustrating a method of generating a layout correction model according to a comparative example, which may be different from some embodiments.

According to a comparative example, points on target edges crossing reference edges may be collectively determined as dissection points, and segments may be determined based on the dissection points. And, according to the comparative example, evaluation points may be uniformly set at an intermediate point of each of the segments. FIG. 6 illustrates dissection points and evaluation points set according to the comparative example.

Comparing FIG. 5 and FIG. 6, the evaluation points set according to the comparative example may be inconsistent with the measurement points.

For example, evaluation points corresponding to segments overlapping the reference pattern, such as a first evaluation point P1, may be set at the same position as the measurement points of FIG. 5. A plurality of evaluation points corresponding to segments not overlapping the reference pattern, such as a second evaluation point P2, may be generated. The evaluation points such as the second evaluation point P2 may have a position, different from those of the measurement points.

The layout correction model generated based on the measurement points described with reference to FIG. 5 may not properly perform learning on data measured at the evaluation points such as the second evaluation point P2. When the data measured at the evaluation points such as the second evaluation point P2 is applied to the layout correction model, overfitting may occur due to insufficient training data. For example, it may be difficult to effectively predict process variation of segments not overlapping the reference pattern.

Since the segments not overlapping the reference pattern may be corrected depending on a result of the overfitting, conformity between a corrected layout and the layout correction model may deteriorate. In addition, since a movement amount of segments not overlapping the reference pattern may be different from a movement amount of adjacent segments, a jog or irregular segment with a nudge or deviation may occur in a corrected pattern.

According to some embodiments, evaluation points of a target edge may be selected as an intermediate point of a section crossing a reference pattern, similar to measurement points. Dissection points may be set such that segments having the evaluation points extend to a space around the reference patterns.

According to some embodiments, process variation prediction and correction in a section of the target edge not overlapping the reference pattern may be effectively performed, and a corrected pattern having a neat shape (i.e., a shape without rough and/or deviant edges) may be acquired.

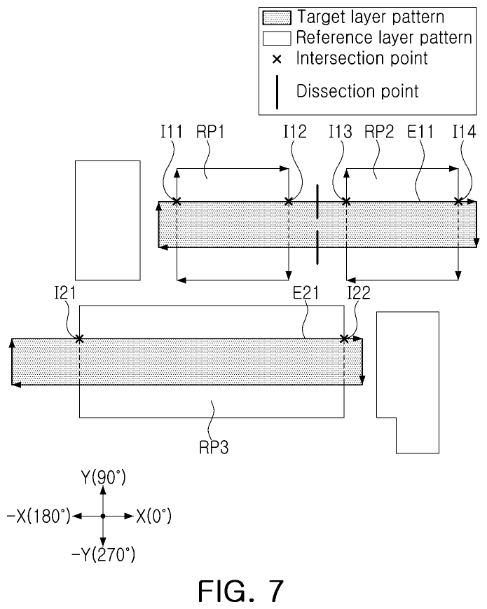

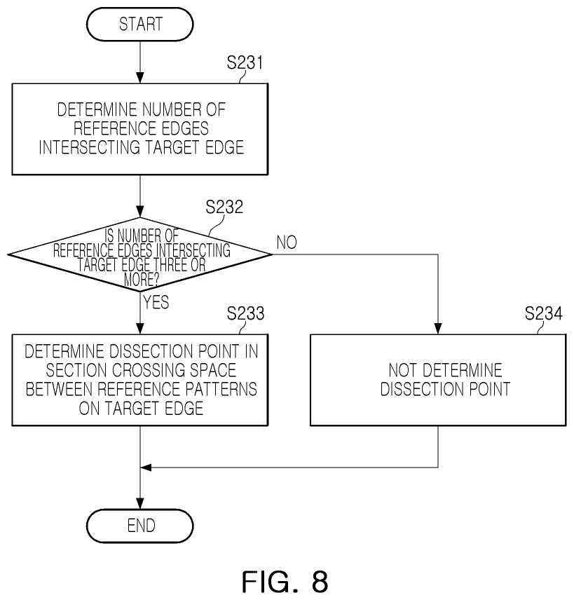

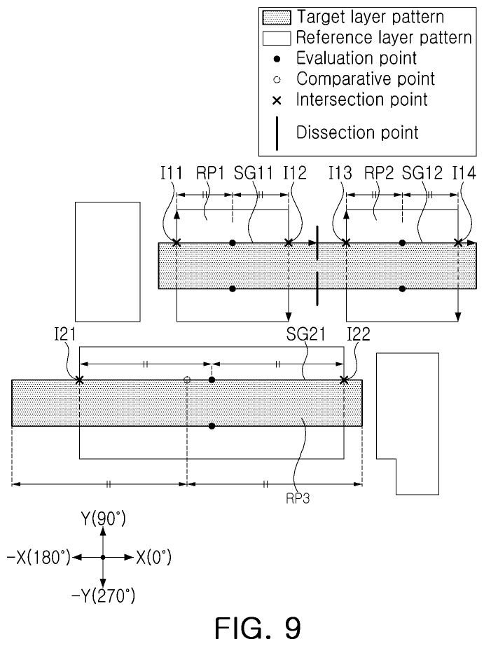

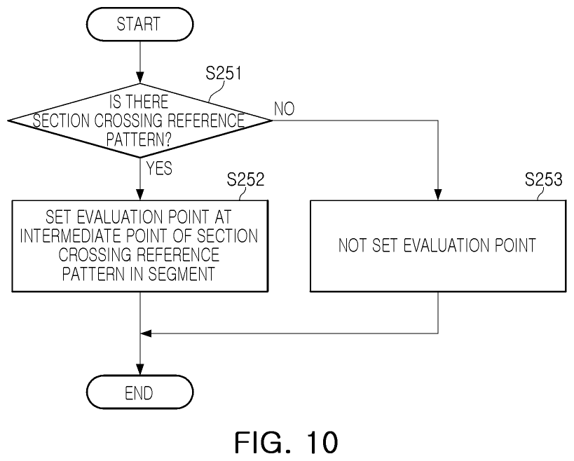

FIG. 7 and FIG. 9 are views illustrating a layout correction method according to some embodiments. FIG. 8 and FIG. 10 are flowcharts illustrating a layout correction method according to some embodiments.

FIGS. 7 and 8 illustrate a method for generating a dissection point according to some embodiments. FIG. 7 is a view illustrating dissection points that may be set in a target layer having the same patterns as those in FIG. 5, and FIG. 8 is a flowchart illustrating a method for generating a dissection point.

Although description is omitted with respect to FIG. 5, referring to FIG. 7, edges may be vectors having respective directions. FIG. 7 illustrates a reference coordinate system indicating a direction of an edge in an XY plane on which a target layer and a reference layer are illustrated. When patterns are composed of one or more rectangles, the edges may have a direction of one of 0 degree, 90 degrees, 180 degrees, or 270 degrees, respectively. FIG. 7 illustrates a direction of a portion of the edges by an arrow.

FIG. 8 illustrates a flowchart of method of determining a dissection point of each of the edges in S23 of FIG. 4 in detail. The method of determining the dissection point of each of the edges may include S231 to S234.

In S231, the number of reference edges intersecting a target edge may be determined. In the example of FIG. 7, a first target edge E11 may intersect four reference edges in an XY plane. FIG. 7 illustrates intersection points I11, I12, I13, and I14, intersecting the four reference edges, on the first target edge E11. A second target edge E21 may intersect two reference edges. FIG. 7 illustrates intersection points I21 and I22, intersecting the two reference edges, on the second target edge E21. A portion of target edges may not intersect the reference edges.

Referring to FIG. 8, in S232, it may be determined whether the number of reference edges intersecting the target edge is three or more. When the number of reference edges intersecting the target edge is three or more, it may mean that the target edge intersects at least one reference pattern and at least one space between the reference patterns in the XY plane.

Referring to FIG. 7, the first target edge E11 intersecting the four reference edges may cross two reference patterns RP1 and RP2. Also, the first target edge E11 may cross a space between a first reference pattern RP1 and a second reference pattern RP2. Also, the second target edge E21 intersecting the two reference edges may cross one reference pattern RP3, and may not cross a space between the reference patterns.

Referring to FIG. 8, when the number of reference edges intersecting the target edge is three or more (“Yes” in S232), a dissection point may be set in a section crossing a space between the reference patterns on the target edge in S233. For example, an intermediate point of the section crossing the space may be set as the dissection point.

When the number of reference edges intersecting the target edge is less than three (“No” in S232), the dissection point may not be determined on the target edge in S234.

Referring to FIG. 7, dissection points set on target edges are illustrated. For example, a dissection point may be set in a section crossing the space between the first reference pattern RP1 and the second reference pattern RP2 on the first target edge E11 crossing the four reference edges. The dissection point may not be set on the second target edge E21 crossing the two reference edges.

A method in which a section crossing a space between reference patterns on a target edge may be identified based on reference edges crossing the target edge may be as follows.

As described above, the edges may have a direction of one of 0 degree, 90 degrees, 180 degrees, or 270 degrees, respectively. For example, the first target edge E11 may have a 0 degree direction. Also, the reference edges intersecting the first target edge E11 may have a direction of 90 degrees or 270 degrees.

A pattern may be defined by a closed curve formed by edges. For example, the edges defining the pattern may proceed in a predetermined direction, for example in a clockwise direction. When the edges proceed clockwise, based on each of the edges, a pattern may be defined on a right side, and a space may be disposed on a left side.

Among edges intersecting the first target edge E11, a space may be disposed in a region adjacent to the reference edges in a 270 degree direction in an X-direction, and a space may be disposed in a region adjacent to the reference edges in a 90 degree direction in a −X-direction. As a result, when a reference edge having a 270 degree direction intersecting the first target edge E11 and a reference edge, adjacent to the reference edge having a 270 degree direction, in the X-direction and having a 90 degree direction are searched for, a section between the intersection point I12 of the reference edge having a 270 degree direction and the intersection point I13 of the reference edge having a 90 degree direction may be identified as a section crossing a space between patterns.

Similarly, in a target edge having 90 degrees, 180 degrees, or 270 degrees, assuming that a direction of the target edge is a reference direction, a space between a reference edge having a 270 degree direction from the reference direction, and a reference edge, adjacent to the reference edge having a 270 degree direction, in the reference direction and having a 90 degree direction from the reference direction, may be identified as a space between reference patterns.

According to some embodiments, on a target edge crossing at least one reference pattern, segments may be set to overlap a reference pattern and a space around the reference pattern.

For example, a first target edge E11 may cross two reference patterns RP1 and RP2 of a reference layer. Based on a dissection point generated between the two reference patterns RP1 and RP2 on the first target edge E11, a segment overlapping a first reference pattern RP1 and a surrounding space thereof and a segment overlapping a second reference pattern RP2 and a surrounding space thereof may be generated. A second target edge E21 may cross a reference pattern RP3. A dissection point may not be generated on the second target edge E21, and a segment overlapping the third reference pattern RP3 and a surrounding space thereof may be generated.

When a segment overlaps a reference pattern and a surrounding space thereof, an evaluation point may be generated in a position overlapping the reference pattern. A shape of a target pattern may be corrected by moving the segment based on a movement amount determined by applying a layout correction model at the evaluation point.

Therefore, a layout correction model learned based on measurement points set in a portion of overlapping the target pattern and the reference pattern may be used, not only to correct a shape of a portion of the target pattern overlapping the reference pattern but also to correct a shape of a portion of the target pattern overlapping a space around the reference pattern.

FIGS. 9 and 10 illustrate a method for generating evaluation points according to some embodiments. FIG. 9 is a view illustrating evaluation points that may be set in segments generated based on the dissection points of FIG. 7, and FIG. 10 is a flowchart illustrating a method for generating an evaluation point.

FIG. 10 illustrates a method of determining an evaluation point for the segments in S25 of FIG. 4 in detail. The method of determining the evaluation point for each of the segments may include S251 to S253.

In S251, it may be determined whether there is a section crossing a reference pattern in a segment. Specifically, a section crossing the reference pattern may be detected based on reference edges intersecting the segment.

Referring to FIG. 9, segments SG11, SG12, and SG21 among a plurality of segments are displayed. The segments SG11, SG12, and SG21 may cross first to third reference patterns RP1 to RP3, respectively. A method of detecting a section crossing the reference pattern in the segments SG11, SG12, and SG21 may be as follows.

As described with reference to FIG. 7, the edges may have a direction of one of 0 degree, 90 degrees, 180 degrees, or 270 degrees, respectively. Directions of segments from which edges are dissected may follow directions of the edges. For example, the segments SG11 and SG12 generated by dissecting the first target edge E11 of FIG. 7 may have a 0 degree direction, respectively.

Among reference edges intersecting a first segment SG11 having a 0 degree direction, a pattern may be defined in a region adjacent to a reference edge having a 90 degree direction in the X-direction, and a pattern may be defined in a region adjacent to a reference edge having a 270 degree direction in the −X-direction. As a result, among the reference edges intersecting the first segment SG11, a section between an intersection point I11 of the reference edge having a 90-degree direction and an intersection point I12 of the reference edge, adjacent to the reference edge having a 90-degree direction, and having a 270-degree direction in the X-direction may be identified as a section crossing a reference pattern.

Similarly, in a segment having a 90 degree, 180 degree, or 270 degree direction, other than the 0 degree direction, based on a reference direction of the segment among intersecting reference edges, a space between an intersection point of a reference edge having a 90 degree direction and an intersection point of a reference edge having a 270 degree direction may be identified as a section crossing a space between reference patterns.

A target layer may also include segments not having a section crossing a reference pattern. For example, when there is 0 or 1 reference edge intersecting a segment, the segment may not have a section crossing the reference pattern. Also, even when a segment has two intersecting edges, when the segment crosses a space between reference patterns, the segment may not have a section crossing a reference pattern.

Referring to FIG. 10, when there is a section crossing a reference pattern in a segment (“Yes” in S251), an evaluation point may be set at an intermediate point of the section crossing the reference pattern in the segment in S252.

When there is no section crossing the reference pattern in the segment (“No” in S251), no evaluation point may be set for the segment in S253.

Referring to FIG. 9, evaluation points set on segments included in a target layer are illustrated. For example, an evaluation point of a segment SG11 may be set at an intermediate point of intersection points I11 and I12, and an evaluation point of a segment SG12 may be set at an intermediate point of intersection points I13 and I14. The evaluation point of the segment SG21 may be set at the intermediate point of the intersection points I21 and I22. In an example of FIG. 9, evaluation points may not be set because there may be no section crossing a pattern of a reference layer in 90 degree direction segments or 270 degree direction segments.

It should be noted that an evaluation point is set not at an intermediate point of a segment, but at an intermediate point of a section crossing a reference pattern in the segment. In FIG. 9, a comparative point representing an intermediate point of the segment SG21 is illustrated. Referring to FIG. 9, the intermediate point of the segment may deviate from an intermediate point of the reference pattern. In some cases, the intermediate point of the segment may deviate from the reference pattern.

According to some embodiments, even though a segment is generated based on a dissection point set in a space between reference patterns, an evaluation point may be set at an intermediate point of a section of the segment crossing a reference pattern, to set a position such that the evaluation point is consistent with a measurement point.

When the evaluation point is set to have a position consistent with the measurement point, conformity between post-formation layouts for learning and post-formation layouts predicted based on the evaluation point may be improved. Therefore, etch skew may be effectively corrected using a layout correction model.

A plurality of reference patterns having a certain shape may overlap a certain target pattern. For example, a plurality of active patterns arranged in one direction may be disposed on a reference layer, and a gate pattern extending in the one direction may be disposed to cross the plurality of active patterns in a target layer. According to some embodiments, when a plurality of reference patterns regularly overlap a target pattern, a corrected layout having a neat shape (i.e., a shape without rough and/or deviant edges) may be acquired.

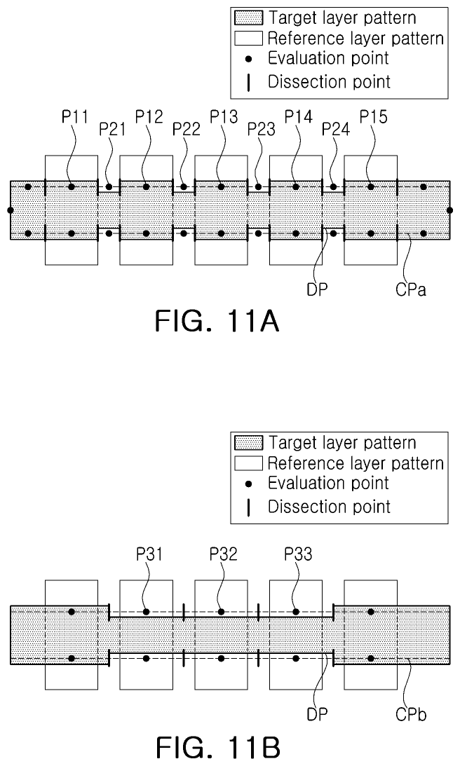

FIGS. 11A and 11B are views for comparing and explaining layout correction results according to a comparative example and some embodiments.

FIG. 11A illustrates a result of correcting a design layout according to a comparative example, as described with reference to FIG. 6, and FIG. 11B illustrates a result of correcting the same design layout according to some embodiments, as described with reference to FIGS. 7 to 10.

Referring to FIG. 11A, a reference layer may include a plurality of reference patterns regularly arranged in one direction. And, a target layer may include a target pattern extending in the direction crossing the plurality of reference patterns. In FIGS. 11A and 11B, a target pattern of a design layout may be referred to as a design pattern DP.

According to the comparative example, points intersecting a reference edge on an edge of the design pattern DP may be uniformly determined as a dissection point, and segments may be determined based on the dissection point. In addition, an intermediate point of each of the plurality of segments may be uniformly determined as a comparative point. FIG. 11A illustrates dissection points and evaluation points according to the comparative example.

Among the evaluation points, first evaluation points P11 to P15 may be respectively set at intermediate points of sections crossing the reference pattern from a target edge, like a measurement point. Therefore, a layout correction model may have sufficient training data for first segments having the first evaluation points P11 to P15. Thus, the first segments may be corrected based on the sufficient training data.

Among the evaluation points, second evaluation points P21 to P24 may be set in a space of a lower layer, and the second evaluation points P21 to P24 may be set in a position, unrelated to the measurement point. Therefore, the layout correction model may have insufficient training data for second segments having the second evaluation points P21 to P24. Thus, the second segments may be overfitted based on the insufficient training data.

The first segments may have similar features to each other. For example, since patterns of the same shape may commonly overlap on a lower layer of the first segments, the predicted degree of etch skew may be similar between the first segments. Therefore, movement amounts of the first segments may be the same or similar to each other.

A movement amount of a first segment, which is normally corrected, may be different from a movement amount of a second segment, which is overfitted. FIG. 11A, the first segment and the second segment may be alternately disposed adjacent to each other. Therefore, correction amounts between adjacent segments may be different. As a result, a jog or irregular segment with a nudge or deviation may occur in a correction pattern CPa.

The jog of the correction pattern CPa may complicate a corrected layout. In addition, when OPC is further performed on the correction pattern CPa, complexity of a final pattern may greatly increase because fine patterns may be added to each corner of the correction pattern CPa. As a result, accuracy of a mask manufactured based on the final pattern may deteriorate, and a defect in a semiconductor chip manufactured using the mask may be caused.

Referring to FIG. 11B, reference patterns and a design pattern DP may be equal to the design pattern DP of FIG. 11A.

According to some embodiments, points included in a section crossing a space between adjacent reference patterns on an edge of the design pattern DP may be determined as a dissection point, and segments may be determined based on the dissection point. For example, on an edge crossing the reference patterns, dissection points may be determined such that one segment crosses a reference pattern and overlaps a space surrounding the reference pattern.

In a segment crossing the reference pattern among the plurality of segments, an intermediate point of a section crossing the reference pattern may be set as an evaluation point. According to some embodiments, evaluation points may be set as criteria consistent with a measurement point. Unlike the comparative example described with reference to FIG. 11A, evaluation points may not be generated in a position corresponding to a space of the reference layer.

Among the evaluation points, third segments having third evaluation points P31 to P33 may have similar features to each other. For example, since patterns of the same shape in the third segments may overlap the reference layer in common, predicted degrees of etch skew may be similar between the third segments. Therefore, correction amounts of the third segments may be equal to or similar to each other.

Referring to FIG. 11B, the third segments may be adjacent to each other. Since the correction amounts may be the same or similar between adjacent segments, a jog in a correction pattern CPb may be alleviated, and a shape of the correction pattern CPb may be refined. Even when OPC is performed on the correction pattern CPb, since the number of corners to which fine patterns are added may be reduced, complexity of a final layout may also be greatly alleviated. As a result, accuracy of a mask manufactured based on the final layout may be improved, and quality of a semiconductor chip manufactured using the mask may be improved.

According to some embodiments, consistency of measurement points and evaluation points may be improved even in a design layout having a reference layer and a target layer including various patterns.

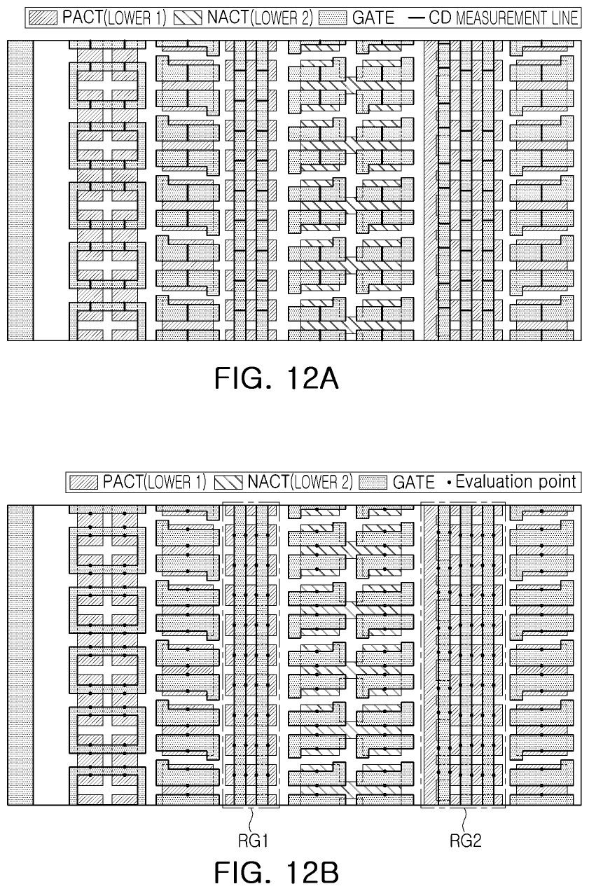

FIGS. 12A and 12B are views illustrating a comparison between a position in which a measurement point is generated and a position in which an evaluation point is generated according to some embodiments.

FIG. 12A is a view illustrating CD measurement lines on which CD is measured based on measurement points in a design layout, and FIG. 12B is a view illustrating evaluation points determined according to some embodiments in the same design layout.

FIG. 12A illustrates first active patterns PACT, which is P-type doped, and second active patterns NACT, which is N-type doped, included in a reference layer in a design layout including the reference layer and a target layer, and illustrates gate patterns GATE included in the target layer.

Measurement points may be set based on an intermediate point of a region in which edges of the gate patterns GATE cross the active patterns PACT and NACT. Referring to FIG. 12A, for the gate patterns GATE of various shapes, CD may be measured at an intermediate point of a region in which the gate patterns GATE and the active patterns PACT and NACT overlap.

As described above, overlapping patterns in a reference layer may affect process variations such as etch skew of patterns in a target layer. As illustrated in FIG. 12A, features of a design layout and a post-formation layout may be measured at the measurement points for the gate patterns GATE having various shapes. In addition, a process variation amount may be determined based on the features, and a layout correction model may be generated by performing machine learning based on the features and the process variation amount. Since a layout correction model may be generated based on data collected for various cases in which target patterns overlap reference patterns, the layout correction model may accurately reflect process variations caused by patterns of a lower layer.

Referring to FIG. 12B, gate patterns GATE of various shapes may be dissected into a plurality of segments based on a space between adjacent active patterns PACT and NACT, and an intermediate point of a section in which the active patterns PACT and NACT overlap in the plurality of segments may be set as an evaluation point. Comparing FIGS. 12A and 12B, positions of the measurement points on both ends of the CD measurement line in FIG. 12A may coincide with positions of the evaluation points in FIG. 12B.

Even when a design layout for learning is different from a design layout for manufacturing, positions of evaluation points of the design layout for manufacturing may be determined to be consistent with positions of measurement points of the design layout for learning. Therefore, even when the design layout for learning is different from the design layout for manufacturing, process variation due to the design layout for manufacturing may be accurately predicted using a layout correction model generated based on data measured at various measurement points.

In addition, as illustrated in first and second regions RG1 and RG2, a design layout may include gate patterns GATE extending in one direction, and active patterns PACT regularly arranged in the one direction and overlapping the gate patterns GATE. For example, a layout for forming a plurality of devices having the same structure, such as a memory device, may have a plurality of active patterns PACT overlapping gate patterns GATE.

Referring to FIGS. 11A and 11B, neat gate patterns may be acquired in a corrected layout, even in FIGS. 12A and 12B in which the plurality of active patterns PACT overlap the gate patterns GATE. Therefore, quality and yield of a semiconductor chip having a repetitive structure, such as a memory device, may be improved.

The present inventive concept is not limited to a case in which a reference layer includes active patterns and a target layer includes gate patterns. For example, the present inventive concept may be applied to various design layouts in which regions formed of different materials are included on an upper surface of a reference layer and a target layer is in contact with the upper surface of the reference layer.

Hereinafter, a mask manufacturing method and a semiconductor chip manufacturing method to which the layout correction method described with reference to FIGS. 1 to 12B is applied will be described.

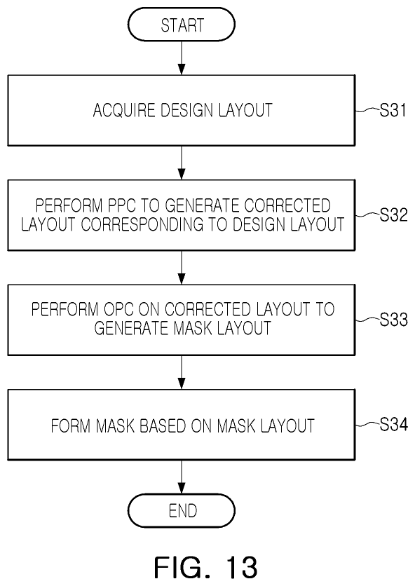

FIG. 13 is a view illustrating a method of manufacturing a mask according to some embodiments.

In S31, a computing system 1000 may acquire a design layout to be corrected from a host computer or a server in a semiconductor manufacturing facility. The design layout may include a structure to be manufactured by a semiconductor process. Design layout correction and mask fabrication may be performed in S32 to S34 such that a mask may accurately transfer the structure to be manufactured to a semiconductor chip.

In S32, the computing system 1000 may perform PPC on the design layout to generate a corrected layout corresponding to the design layout.

According to some embodiments, PPC of a target layer included in the design layout may be performed with reference to a reference layer below the target layer. Specifically, a PPC model for performing the PPC may be learned based on data measured at measurement points set at an intermediate point of a section crossing reference patterns of the reference layer on edges of the target layer.

Furthermore, a target edge including patterns of the target layer, when the target edge crosses a space between the reference patterns of the reference layer, may be dissected into a plurality of segments at the intermediate point of the section crossing the space. In a segment crossing a reference pattern among the plurality of segments, an intermediate point of a section crossing the reference pattern may be set as an evaluation point.

Data measured at the evaluation point may be applied to the PPC model to determine a movement amount of the segment, and may move the segment to correct patterns of the target layer.

In S33, the computing system 1000 may perform OPC on the corrected layout to generate a mask layout. Specifically, a final mask layout may be generated by predicting and analyzing an optical proximity effect in an exposure process in advance, and further correcting the corrected layout according to the analysis result. For example, the corrected layout may be applied to an OPC model, such that fine patterns may be added to a corner of a pattern including at least one rectangle.

In S34, the computing system 1000 may form a mask based on the mask layout. For example, the mask layout may include at least a reference layer and a target layer. Each of the layers included in the mask layout may be prepared as mask data, the mask data may be input to a mask exposure facility, and a mask may be manufactured by the exposure facility.

According to some embodiments, a corrected layout generated by performing PPC based on evaluation points set to be consistent with measurement points may effectively predict and compensate for process variations.

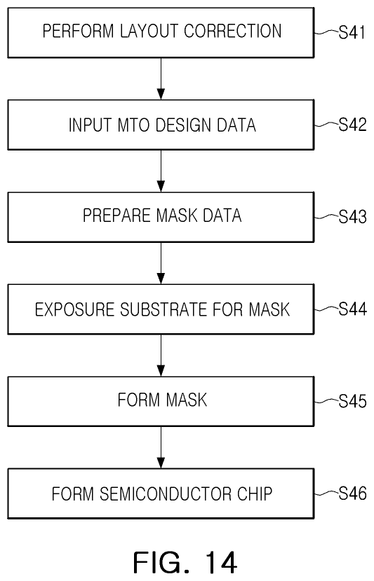

FIG. 14 is a view illustrating a method of manufacturing a semiconductor chip according to some embodiments.

In S41, a mask layout may be generated by performing layout correction on a design layout. S41 may include S32 and S33, described with reference to FIG. 13.

In S42, a mask-tape-out (MTO) design data may be input, after the layout correction is performed, as described above. The MTO design data may refer to mask design data for which the layout correction has been completed. The MTO design data may have a graphic data format used in electronic design automation (EDA) software or the like. For example, the MTO design data may have data formats such as a graphic data system (GDS2), an open artwork system interchange standard (ASIS), or the like.

In S43, mask data preparation (MDP) may be performed. The mask data preparation may include, for example, format conversion called fracturing, augmentation of a barcode for machine reading, a standard mask pattern for inspection, a job deck, or the like, and verification in automated and manual manners. In this case, the job deck may include generating a text file related to a series of commands such as arrangement information of multiple mask files, a standard dose, an exposure speed or method, or the like.

The format conversion, e.g., fracturing, may include a process of dissecting the MTO design data for each region and changing to have a format for an electron beam exposure machine. For example, the fracturing may include data manipulation such as scaling, data sizing, data rotation, pattern reflection, color inversion, or the like. In the conversion process through fracturing, data for numerous systematic errors that may occur during a transfer process from design data to an image on the wafer may be corrected. A data correction process for the systematic errors may be referred to as mask process correction (MPC). For example, line width adjustment called CD adjustment, an operation of increasing pattern arrangement accuracy, or the like may be included in the data correction process. In addition, the data correction process may be a process performed in advance for the mask process correction. In this case, the systematic errors may be caused by distortion generated in an exposure process, a mask development and etching process, a wafer imaging process, or the like.

The mask data preparation may include the MPC. The MPC refers to a process of correcting errors generated during the exposure process, e.g., the systematic errors. In this case, the exposure process may be a concept generally including electron beam writing, developing, etching, baking, or the like. Additionally, data processing may be performed prior to the exposure process. Data processing may be a kind of pre-processing of mask data, and may include a grammar check on mask data, an exposure time prediction, or the like.

In S44, a mask substrate may be exposed based on the mask data. In this case, exposure may include, for example, electron beam writing. In this case, the electron beam writing may be performed in a gray writing method using, for example, a multi-beam mask writer (MBMW). Also, the electron beam writing may be performed using a variable shape beam (VSB) exposure machine.

After the mask data preparation and before the exposure process, a process of converting the mask data into pixel data may be performed. The pixel data may be data directly used for actual exposure, and may include data on shapes to be exposed, and data on doses allocated to each of the shapes. In this case, the data on shapes may be bit-map data obtained by converting shape data, which is vector data, by rasterization or the like.

After the exposure process, a series of processes for forming a mask may be performed in S45. A series of processes may include, for example, developing, etching, cleaning, or the like. In addition, the series of processes for forming a mask may include a measurement process, a defect inspection or defect repair process. In addition, a pellicle application process may be included. In this case, the pellicle application process may include a process of attaching a pellicle to protect a mask surface from subsequent contamination during delivery of the mask and a useful lifespan of the mask when it may be confirmed that there is no contaminant particles or chemical stains by final cleaning and inspection.

When the mask is manufactured, a semiconductor device may be formed by performing various semiconductor processes on a semiconductor substrate, such as a wafer or the like, using the mask manufactured in S46. For reference, a process using a mask may typically include a patterning process by an exposure process. A desired pattern may be formed on the semiconductor substrate or a material layer by a patterning process using such a mask.

The semiconductor process may include a deposition process, an etching process, an ion process, a cleaning process, or the like. In this case, the deposition process may include various material layer formation processes such as CVD, sputtering, spin coating, or the like. The ion process may include processes such as ion implantation, diffusion, heat treatment, or the like. The semiconductor process may include a packaging process of mounting a semiconductor device on a PCB and sealing the same with an encapsulant, and may also include a test process of testing the semiconductor device or package.

A layout correction method according to some embodiments may set a dissection point and an evaluation point on an edge of patterns of a target layer in consideration of patterns of a lower layer to perform layout correction, to correct a deformation in circuit pattern by the lower layer.

A layout correction method according to some embodiments may select a measurement point for generating a layout correction model based on patterns of a lower layer, and may set an evaluation point for applying the layout correction model in a position consistent with the measurement point, to generate a corrected layout pattern that allows a designed circuit pattern to be accurately transferred onto a wafer.

A layout correction method according to some embodiments may set a dissection point to overlap segments not only a pattern of a lower layer but also a space around the pattern, and move the segments to perform layout correction, to correct a pattern crossing a plurality of patterns of a lower layer to have a neat shape.

Problems to be solved by the present inventive concept are not limited to the problems mentioned above, and other problems not mentioned will be clearly understood by those skilled in the art from the above description.

While example embodiments have been illustrated and described above, it will be apparent to those skilled in the art that modifications and variations could be made without departing from the scope of the present inventive concept as defined by the appended claims.

What is claimed is:

1. A layout correction method for a semiconductor device, comprising:
receiving a design layout including at least a target layer and a reference layer;
detecting target edges comprising target patterns in the target layer, and detecting reference edges comprising reference patterns in the reference layer;
determining a dissection point in a section intersecting a space between reference patterns on a target edge having three or more intersecting reference edges, among the target edges;
generating segments by dissecting the target edges based on dissection points set for the target edges, wherein the dissection points comprise the dissection point;
setting an evaluation point at an intermediate point of a section intersecting a reference pattern among the reference patterns on a segment intersecting the reference pattern, among the segments;
determining respective movement amounts of segments having evaluation points comprising the evaluation point set on the segments by inputting a feature measured at the evaluation points to a layout correction model;
generating a corrected layout by moving the segments based on the movement amount; and
forming a mask based on the corrected layout.

2. The layout correction method of claim 1, wherein the layout correction model comprises a model that was machine-learned based on data measured at measurement points that are at an intermediate point of a section intersecting a pattern of a reference layer on an edge of the target layer, for determining a design layout for learning and a post-formation layout for learning.

3. The layout correction method of claim 1, wherein the determining a dissection point comprises setting an intermediate point of a section intersecting the space as the dissection point.

4. The layout correction method of claim 1, wherein the determining a dissection point comprises determining the space between the reference patterns, based on a direction of the reference edges intersecting the target edge.

5. The layout correction method of claim 4, wherein the target edges and the reference edges have a direction of 0 degrees, 90 degrees, 180 degrees, or 270 degrees,
wherein the target patterns are defined by edges forming a closed curve among the target edges, the reference patterns are defined by edges forming a closed curve among the reference edges, and the closed curve is referenced in a clockwise direction,
wherein the determining the space between the reference patterns comprises, after setting a direction of the target edge as a reference direction, determining a space between a first reference edge among the reference edges having a direction of 270 degrees from the reference direction and a second reference edge among the reference edges adjacent to the first reference edge in the reference direction and having a direction of 90 degrees from the reference direction, as the space between the reference patterns.

6. The layout correction method of claim 1, wherein the setting an evaluation point comprises, after setting a direction of the segment as a reference direction, determining a space between a third reference edge among the reference edges having a direction of 90 degrees from the reference direction and a fourth reference edge among the reference edges adjacent to the third reference edge in the reference direction and having a direction of 270 degrees from the reference direction, as the section intersecting the reference pattern.

7. The layout correction method of claim 1, wherein the reference layer has patterns that overlap patterns of the target layer in the semiconductor device in a direction perpendicular to a surface of the semiconductor device.

8. The layout correction method of claim 1, wherein the reference patterns comprise active patterns of the semiconductor device, and the target patterns comprise gate patterns of the semiconductor device.

9. The layout correction method of claim 1, wherein the generating segments comprises determining a target edge for which a dissection point is not set as a single segment.

10. The layout correction method of claim 1, wherein the determining the respective movement amounts of segments having evaluation points set on the segments comprises predicting a process variation of the design layout by inputting the feature into the layout correction model, and determining the respective movement amounts of the segments to compensate for the process variation.

11. The layout correction method of claim 10, wherein the feature comprises at least one of a critical dimension (CD), a distance from an adjacent pattern, or a pattern density in a region of a predetermined range.

12. The layout correction method of claim 1, wherein the determining the respective movement amounts of segments having evaluation points set on the segments comprises predicting an etch step difference of a post-formation layout corresponding to the design layout by inputting a critical dimension (CD) measured based on the evaluation points into the layout correction model, and determining the respective movement amounts of the segments to compensate for the etch step difference that was predicted.

13. A layout correction method for a semiconductor device, comprising:
measuring data at measurement points that are at an intermediate point of a section intersecting a reference pattern of a reference layer on a target edge of target layers, for determining a design layout and a post-formation layout;
generating a layout correction model by performing machine learning based on the data that was measured;
dissecting edges intersecting two or more reference patterns, among target edges including the target edge of a target layer among the target layers, into segments respectively intersecting one reference pattern of the two or more reference patterns, in a design layout for manufacturing the semiconductor device;
generating a corrected layout by applying data measured at evaluation points set by criteria consistent with the measurement points, for the segments, to the layout correction model; and
forming a mask based on the corrected layout.

14. The layout correction method of claim 13, wherein the post-formation layout is an after-cleaning-inspection (ACI) layout or an after-develop-inspection (ADI) layout.

15. The layout correction method of claim 13, wherein the data at measurement points comprises at least one of a critical dimension (CD), a distance between the measurement points and an adjacent pattern, or a pattern density in a region of a predetermined range from one or more of the measurement points.

16. The layout correction method of claim 15, wherein the data at measurement points further comprises an etch step difference determined based on first CDs measured in the design layout and second CDs measured in the post-formation layout.

17. The layout correction method of claim 13, wherein the generating a corrected layout comprises predicting a process variation by applying data measured at the evaluation points to the layout correction model, and correcting a shape of a pattern of the target layers by moving the segments to compensate for the process variation that was predicted.

18. The layout correction method of claim 13, further comprising, in each of the segments, setting an evaluation point of the evaluation points at an intermediate point of a section intersecting a pattern of the reference layer.

19. A mask manufacturing method for a semiconductor device, comprising:
receiving a design layout including at least a target layer and a reference layer below the target layer;
generating segments by dissecting target edges of the target layer based on sections intersecting a space between reference patterns of the reference layer;
setting an evaluation point at an intermediate point of a intersecting section intersecting a reference pattern, in segments having the intersecting section, respectively, among the segments that were generated;
generating a corrected layout by applying respective features at evaluation points to a process proximity correction (PPC) model and by moving segments having the evaluation points according to a result of the applying;
generating a mask layout by performing optical proximity correction (OPC) on the corrected layout; and
manufacturing a mask based on the mask layout.

20. The mask manufacturing method of claim 19, wherein one or more of the evaluation points are set by criteria consistent with measurement points used in machine learning of the PPC model.
